(19) United States
(12) Patent Application Publication
(10) Pub. No.: US 2025/0022894 A1
(43) Pub. Date: Jan. 16, 2025

(54) PIXEL

(71) Applicant: STMicroelectronics International N.V., Geneva (CH)

(72) Inventors: Giulio FORCOLIN, Edinburgh (GB); Raul Andres BIANCHI, Myans (FR); Isobel NICHOLSON, Edinburgh (GB)

(73) Assignee: STMicroelectronics International N.V., Geneva (CH)

(21) Appl. No.: 18/761,207

(22) Filed: Jul. 1, 2024

(30) Foreign Application Priority Data
Jul. 10, 2023 (EP) 23306169.6

(51) Int. Cl. H01L 27/146; H01L 31/107; H01L 31/18

(52) U.S. Cl. CPC H01L 27/14607; H01L 27/14669; H01L 31/1804; H01L 31/107

(57) ABSTRACT

A pixel includes, on a first face, first trenches extending parallel to a first direction and regularly spaced in a second direction (orthogonal to the first direction) and second trenches extending parallel to the second direction and regularly spaced in the first direction. The first trenches include first notches, each first notch extending from a first trench and being aligned with a corresponding second trench. The second trenches include second notches, each second notch extending from a second trench and being aligned with a corresponding first trench.

### PRIORITY CLAIM

This application claims the priority benefit of European Application for Patent No. 23306169.6, filed on Jul. 10, 2023, the content of which is hereby incorporated by reference in its entirety to the maximum extent allowable by law.

### TECHNICAL FIELD

The present disclosure relates generally to electronic circuits, for example integrated electronic circuits. The present disclosure is more particularly related to an integrated circuit pixel, for example a pixel implemented in a matrix of identical pixels in a light sensor, for example a time of flight (ToF) sensor.

### BACKGROUND

In order to increase the light path in the silicon of a photodetector of a pixel, for example of the Single Photon Avalanche Diode (SPAD), it is known to add diffractive structures on a face of the pixel which is intended to receive light.

FIG. 1 shows an example of a face 100 of a silicon photodetector of a pixel Pix1, the face 100 being intended to receive light and being provided with such diffractive structures. More particularly, FIG. 1 is a top view of this structured face 100. The FIG. 1 is a simplified reproduction of FIG. 2 of United States Patent Application Publication No. 2022/0085084 (corresponding to French Patent No. 3 114 190 B1), incorporated herein by reference.

The face 100 has two opposite sides 102 and 104 parallel to each other and to a direction Y, and two opposite sides 106 and 108 parallel to each other and to a direction X. The direction X is perpendicular to the direction Y. The face 100 has a square shape in a top view of the pixel Pix1.

The face 100 is one face of a silicon portion forming a photodetector of the pixel Pix1. The photodetector of pixel Pix1 is, for example, laterally delimited by insulation structure 110. The structure 110 is, for example, a capacitive deep trench insulation (CDTI).

The pixel Pix1 comprises a plurality of trenches 112 extending in length in the direction X, and a plurality of trenches 114 extending in length in the direction Y. In FIG. 1, only a few of the trenches 112 and 114 are referenced to not overload the Figure. In FIG. 1, the trenches 112 and 114 are indicated by hatched lines.

A first part of trenches 112 extends from the side 102 toward the side 104, and a second part of trenches 112 extends from the side 104 toward the side 102. Similarly, a first part of trenches 114 extends from the side 106 toward the side 108, and a second part of trenches 114 extends from the side 108 toward the side 106. The trenches 112 of the first part of trenches 112 do not join the trenches 112 of the second part of trenches 112. Similarly, the trenches 114 of the first part of trenches 114 do not join the trenches 114 of the second part of trenches 114. Further, the trenches 112 do not cross the trenches 114.

United States Patent Application Publication No. 2022/0085084 (corresponding to French Patent No. 3 114 190 B1) further disclose other examples of a face of a silicon photodetector of a pixel provided with first and second trenches, where the first trenches are perpendicular to the second trenches and the first trenches do not cross the second trenches.

These first and second trenches allow to increase the light path in the silicon of the photodetector, thus increasing the quantum efficiency of the pixel. For example, increasing the light path is particularly important when the light received and sensed by the pixel is infra-red light having wavelengths, for example, comprised between 750 nm and 1400 nm, for example a wavelength equal to approximately 950 nm, preferably equal to 950 nm.

Other examples of pixel having a photodetector in silicon where a face of the silicon portion corresponding to the photodetector is provided with first trenches and second trenches perpendicular to the first trenches are known.

There is a need to increase the light path in the silicon of a photodetector of pixel with respect to the known pixels provided with first and second trenches has described above.

There is a need in the art to address all or some of the drawbacks of known pixels provided with first and second trenches as described above.

### SUMMARY

In an embodiment, a pixel comprises: a silicon portion having a first face configured to received light, for example infra-red light; first trenches parallel to a first direction and regularly spaced in a second direction perpendicular to the first direction, the first trenches penetrating into the silicon portion from the first face; and second trenches parallel to the second direction and regularly spaced in the first direction, the second trenches penetrating into the silicon portion from the first face. In a central region of the first face, the first trenches comprise first notches each penetrating into the silicon from the first face, extending from a first trench comprising said notch toward a neighboring first trench without reaching said neighboring first trench, and being aligned with a corresponding second trench. In the central region, the second trenches comprise second notches each penetrating into the silicon from the first face, extending from a second trench comprising said notch toward a neighboring second trench without reaching said neighboring second trench, and being aligned with a corresponding first trench.

According to one embodiment, the first face has two first sides parallel to the first direction and two second sides parallel to the second direction.

According to one embodiment, the first face comprises: a first region extending from a first one of the first sides toward the central region, the first region comprising only second trenches; a second region extending from a second one of the first sides toward the central region, the second region comprising only second trenches; a third region extending from a first one of the second sides toward the central region, the third region comprising only first trenches; a fourth region extending from a second one of the second sides toward the central region, the fourth region comprising only first trenches.

According to one embodiment, the first and second trenches are devoid of notches outside the central region.

According to one embodiment, at least one V-shaped pattern made of one first trench and one second trench is arranged in each corner of the first face, outside the central region.

According to one embodiment, in each corner of the first face, said at least one V-shaped pattern arranged in said corner is symmetrical with respect to a diagonal of the first face extending from said corner, and has its apex turned toward the center of the first face.

According to one embodiment, for each corner of the first face: the pixel comprises a plurality a V-shaped patterns each having one first trench and one second trench, the V-shaped patterns are successively and regularly arranged from said corner toward the center of the first face, each of said V-shaped patterns has its apex turned toward the center of the first face, each of said V-shaped patterns is symmetrical with respect to a diagonal extending from said corner, and the first trenches of these V-shaped patterns comprise first notches in the central region and/or the second trenches of these V-shaped patterns comprise second notches in the central region.

According to one embodiment, in the central region, the first trenches are aligned on first lines of a grid pattern and the second trenches are aligned on second lines of a grid pattern, the first notches being aligned on the second lines of the grid pattern and the second notches being aligned with the first lines.

According to one embodiment, in the first direction, the central region has a length comprised between 50 and 70% of the length of each first side, and, in the second direction, the central region has a length comprised between 50 and 70% of the length of each first side.

According to one embodiment, in the central region, the first and second trenches together with the first and second notches form a pattern similar to a grid pattern.

According to one embodiment, the first and second trenches together with the first and second notches form a pattern having a 90° rotational symmetry with respect to the center of the first face.

According to one embodiment, the first trenches are disposed with a first pitch in the second direction and the second trenches are disposed with a second pitch in the first direction, the first and second pitches being equal to each other and, for example, comprised between 300 and 600 nm, preferably equal to approximately 450 nm.

According to one embodiment, the length of the first notches in the second direction and the length of the second notches in the first direction are comprised between 40 and 60% of the first and second pitches.

According to one embodiment, a width of the first trenches is equal to a width of the second trenches, the width of the first and second trenches being comprised between 150 and 250 nm, for example equal to approximatively 200 nm.

One embodiment provides a method of fabricating the pixel described above, the method comprising: forming a hard mask on the first face of the pixel; forming a photoresist mask on the hard mask; patterning the photoresist mask in order to form therein a first opening exposing the hard mask at each location of a first trench, each location of a second trench, each location of a first notch and each location of a second notch; etching, through said first openings, second openings in the hard mask; and etching, through said second openings, the first and second trenches and the first and second notches in the silicon portion.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1, previously described, is a schematic top view of a face of a silicon photodetector of a pixel;

FIG. 2 is a schematic top view of an ideal embodiment of a face of a silicon photodetector of a pixel;

FIG. 3 is a schematic top view of an embodiment of a face of a silicon photodetector of a pixel;

FIG. 4 is a schematic top view of another embodiment of a face of a silicon photodetector of a pixel;

FIG. 5 is a schematic top view of yet another embodiment of a face of a silicon photodetector of a pixel; and

FIG. 6 is a schematic top view of yet another embodiment of a face of a silicon photodetector of a pixel.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. In particular, the implementation of the described pixels in a light sensor, for example a time of flight sensor, comprising at least one of the described pixels, for example a matrix of pixels identical to one of the described pixels, has not been described, the implementation of such a sensor being in the abilities of those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following disclosure, a pixel configured to operate with one or several wavelengths in the near infrared, that is to say in the range from 750 nm to 1400 nm, for example a pixel configured to operate with a wavelength equal to substantially 940 nm, is considered as an example. The photodiode of the pixel is further considered to be made of silicon, which has a poor light absorption for these wavelengths. It is further considered, as an example, that the pixel is configured so that its photodiode operates in a single photon avalanche mode, or, say in other words, that the pixel comprises a single photon avalanche diode or SPAD.

Embodiments herein propose to increase the quantum efficiency of a photodiode of a pixel by providing a structure for dispersing, out of the normal incident angle, the light which reaches the photodiode. As a result, the light pathlength in the photodiode is increased, which leads to an increase of the quantum efficiency.

FIG. 2 is a schematic top view of an ideal embodiment of a face 200 of a silicon photodetector of a pixel Pix2.

The face 200 is intended to receive light and is provided with structurations (for example, diffractive structures) made by trenches 202 and trenches 204.

The face 200 has two opposite sides 206 and 208 parallel to each other and to a direction Y, and two opposite sides 210 and 212 parallel to each other and to a direction X. The direction X is perpendicular to the direction Y. The face 200 has, preferably, a square shape.

The face 200 is one face of a silicon portion forming a photodetector of the pixel Pix2. The photodetector of pixel Pix2 is, for example, laterally delimited by insulation structure 214. The structure 214 is, for example, a capacitive deep trench insulation (CDTI). In an alternative example, the structure 214 is a deep trench insulation (DTI).

The trenches 202 extend in length in the direction Y, and the trenches 204 extend in length in the direction X. In FIG. 2, only a few of the trenches 202 and 204 are referenced to not overload the Figure. In FIG. 2, the trenches 202 and 204 are designated by hatched lines.

The trenches 202 are regularly spaced in the X direction. Said otherwise, the trenches 202 are arranged with a pitch P1. Similarly, the trenches 204 are regularly spaced in the Y direction. Said otherwise, the trenches 204 are arranged with a pitch P2. The pitch P1 is equal to the pitch P2.

For example, for a received light in the infra-red, the pitches P1 and P2 are comprised between 300 and 600 nm, for example equal to approximately 450 nm, preferably equal to 450 nm.

For example, the width of the trenches 202 (measured in the direction X) is equal to the width of the trenches 204 (measured in the direction Y). For example, for a received light in the infra-red, the width of the trenches 202 and 204 is comprised between 150 and 250 nm, for example equal to approximately to 200 nm.

Although this is not visible in the view of the FIG. 2, the trenches 202 and 204 penetrate into the silicon of the photodetector from the face 200. For example, for a received light in the infra-red, the trenches 202 and 204 penetrate into the silicon on a depth comprised between 200 and 300 nm, for example a depth equal to approximatively 250 nm.

The face 200 comprises a central region 216, delimited in dotted lines in FIG. 2. The region 216 has a length measured in the direction X, which is comprised between 50 and 70% of the length of the sides 206 and 208, a length, measured in the direction Y, which is comprised between 50 and 70% of the length of the sides 210 and 212. Preferably, the central region 216 is a square shape.

In the ideal embodiment of FIG. 2, the trenches 202 cross the trenches 204 in the central region 216, in order to form a grid pattern in the whole central region 216. Said otherwise, in the central region 216, the trenches 202 are aligned on first lines of a grid pattern and the trenches 204 are aligned on second lines of a grid pattern, the first lines being orthogonal to the second lines and being parallel to the direction Y.

In the ideal embodiment of FIG. 2, the pixel Pix2 comprises a region which extends from the side 206 toward, preferably until, the central region 216 and which comprises only trenches 204, or said otherwise, which is devoid of trenches 202. The pixel Pix2 further comprises a region which extends from the side 208 toward, preferably until, the central region 216 and which comprises only trenches 204, or said otherwise, which is devoid of trenches 202. The pixel Pix2 comprises a region which extends from the side 210 toward, preferably until, the central region 216 and which comprises only trenches 202, or said otherwise, which is devoid of trenches 204. The pixel Pix2 further comprises a region which extends from the side 212 toward, preferably until, the central region 216 and which comprises only trenches 202, or said otherwise, which is devoid of trenches 204.

In the ideal embodiment of FIG. 2, the pixel Pix2 comprises, in each corner of the face 200, a V-shaped pattern made of one trench 202 and one trench 204. In each corner, this V-shaped pattern has its apex turned toward the center O of the face 200. Preferably, in each corner of the face 200, the V-shaped pattern arranged in this corner is symmetrical with respect to a diagonal of the face 200 which extends from this corner.

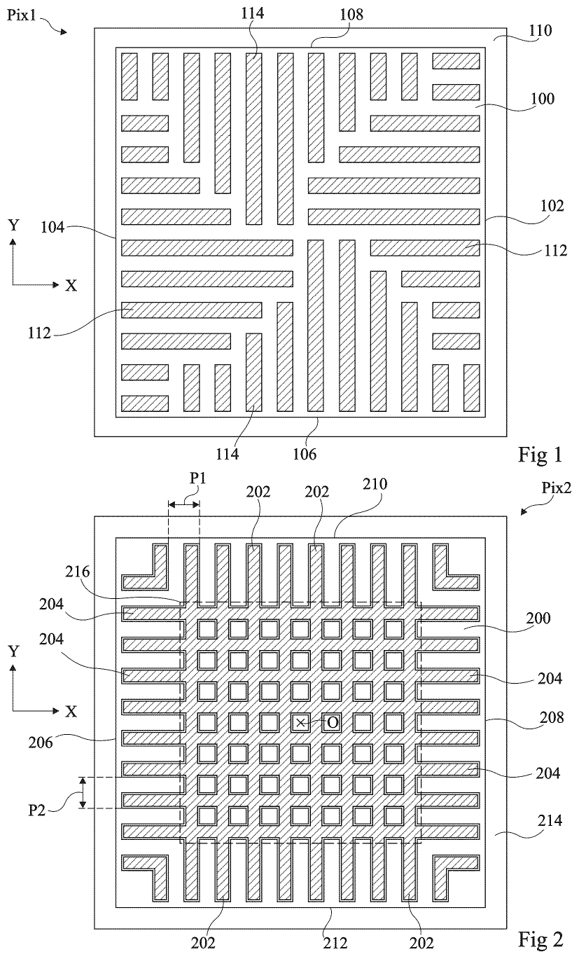

It has been found by simulation that the pixel Pix2 of FIG. 2 has an optimized pattern made of trenches 202 and 204 for improving the light absorption in the photodetector of the Pix2 with respect to a pixel having a similar photodetector but with trenches 112 and 114 of the type described in relation with FIG. 1.

However, in view of the dimension of the trenches 202 and 204 and of their pitch P1 and P2, the pixel Pix2 may be not manufacturable with the usual microelectronic fabrication processes. For example, when using a mask made of a photoresist patterned with openings at the location of the trenches 202 and 204, the portions of the photoresist left in place between these opening may not adhere sufficiently and be stripped out, which lead to defect in the pattern of the trenches 202 and 204 compared to the one described in relation with FIG. 2. This is, for example, more particularly the case when the dimensions of the trenches 202 and 204 and their pitches P1 and P2 are chosen, or optimized, for a received light in the infra-red.

Thus, rather than providing trenches 202 and 204 which form a grid pattern in the central region 216 of the pixel Pix2 as shown in FIG. 2, it is here proposed a pixel Pix3 similar to pixel Pix2 but in which the trenches 202 and 204 are replaced by similar trenches respectively 302 and 304 which comprise, in a central region 316 of the pixel Pix3, notches 320 and 322.

More particularly, the trenches 302 are parallel to the direction Y and the trenches 304 are parallel to the direction 306. Further, the trenches 302 comprise, in the central region 316, notches 320 which each extend in the direction X from a corresponding trench 302 toward a neighboring trench 302 but without reaching this neighboring trench 302, the notch 320 being aligned in the X direction with a trench 304. Similarly, the trenches 304 comprise, in the central region 316, notches 322 which each extend in the direction Y from a corresponding trench 304 toward a neighboring trench 304 but without reaching this neighboring trench 304, the notch 322 being aligned in the Y direction with a trench 302.

Thus, in the central region 316, the pattern formed by the trenches 302 and 304 and the notches 320 and 322 is similar to a grid pattern but is not identical to a grid pattern (i.e., the pattern is grid-like). This allows to improve the absorption in the photodetector of the pixel Pix3 in a manner similar to the grid pattern of the pixel Pix2, and, in the same time, this allows for the pixel Pix3 to be manufactured using usual steps of the microelectronic fabrication processes.

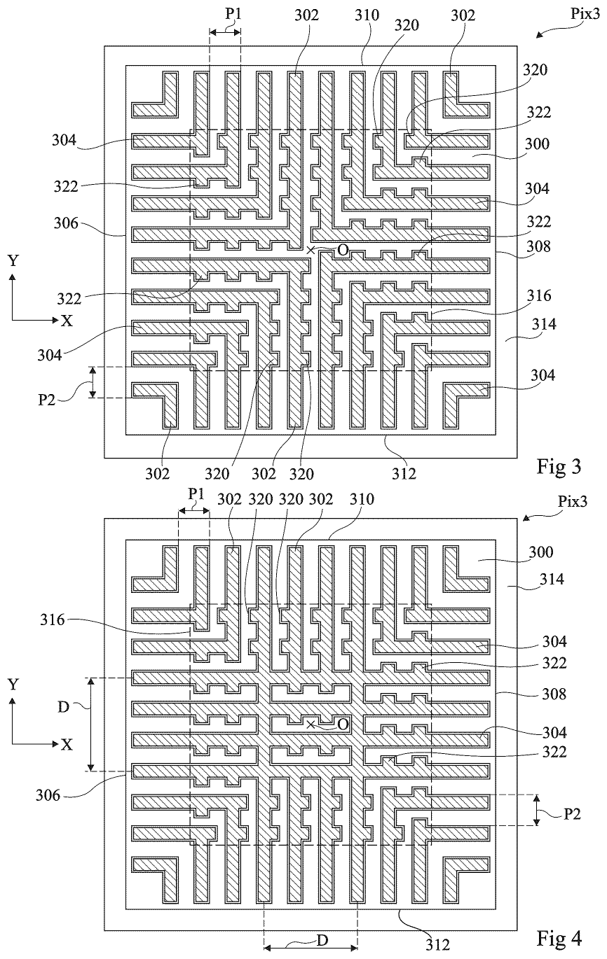

FIG. 3 illustrate an embodiment of the pixel Pix3. More particularly, the FIG. 3 is a schematic top view of an embodiment of a face 300 of a silicon photodetector of the pixel Pix3.

The face 300 is intended to receive light and is provided with structurations (diffractive structures, for example) made by trenches 302 and trenches 304.

The face 300 has two opposite sides 306 and 308 parallel to each other and to a direction Y, and two opposite sides 310 and 312 parallel to each other and to a direction X. The direction X is perpendicular to the direction Y. The face 300 has, preferably, a square shape.

The face 300 is one face of a silicon portion forming a photodetector of the pixel Pix3. The photodetector of pixel Pix3 is, for example, laterally delimited by insulation structure 314. The structure 314 is, for example, a capacitive deep trench insulation (CDTI). In an alternative example, the structure 314 is a deep trench insulation (DTI).

The trenches 302 extend in length in the direction Y, and the trenches 304 extend in length in the direction X. In FIG. 3, only a few of the trenches 302 and 304 are referenced to not overload the Figure. In FIG. 3, the trenches 302 and 304 are hatched.

The trenches 302, respectively 304, are similar to the trenches 202, respectively 204, previously described, with the difference that the trenches 302 and 304 do not form a complete grid pattern in the central region 316 of the pixel Pix3. Thus, unless specified otherwise, all that have been indicated for the trenches 202 and 204 applies to the trenches respectively 302 and 304. Furthermore, in the pixel Pix3, the central region 316 of the face 300 (delimited by dotted lines in FIG. 3) is similar to the central region 216 of the face 200 of the pixel Pix2. Thus, unless indicated otherwise, all that have been described for the region 216 applies to the central region 316. In particular, the dimensions of the region 316 with respect to the sides 306, 308, 310 and 312 are identical to the dimensions of the region 216 with respect to the sides 206, 208, 210 and 212 respectively.

As indicated before and shown on FIG. 3, in the central region 316, the trenches 302 comprise notches 320 and the trenches 304 comprise notches 322. Only a few of the notches 320 and 322 are referenced in FIG. 3 in order to not overload the Figure. Thus, in the central region, the trenches 302 and the notches 322 are aligned on first lines of a grid pattern, the trenches 304 and the notches 324 are aligned on second lines of the grid pattern, the first lines being parallel to the direction Y and the second lines being aligned with the direction X. Preferably, there is no notch 322 which is not aligned with a corresponding trench 302, and there is no notch 324 which is not aligned with a corresponding trench 304.

The notches 320 and 322 penetrate into the silicon of the pixel Pix3 from the face 300. Preferably, the notches 320 and 322 penetrate the silicon of the photodetector of the pixel Pix3 on the same depth as the trenches 302 and 304.

Preferably, the width of the notches 322 (measured in the direction X) is equal to the width of the trenches 302, and the width of the notches 324 (measured in the direction Y) is equal to the width of the trenches 304.

Preferably, the length of the notches 322 (measured in the direction Y) and the length of the notches 324 (measured in the direction X) are comprised between 40 and 60% of respectively the pitch P2 of the trenches 304 and the pitch P1 of the trenches 302, the pitches P1 and P2 being preferably equal to each other.

Preferably, the pixel Pix3 comprises, similarly to pixel Pix2: a first region which extends from the side 306 toward, preferably until, the central region 316 and which comprises only trenches 304, or said otherwise, which is devoid of trenches 302; a second region which extends from the side 308 toward, preferably until, the central region 316 and which comprises only trenches 304, or said otherwise, which is devoid of trenches 302; a third region which extends from the side 310 toward, preferably until, the central region 316 and which comprises only trenches 302, or said otherwise, which is devoid of trenches 304; and a fourth region which extends from the side 312 toward, preferably until, the central region 316 and which comprises only trenches 302, or said otherwise, which is devoid of trenches 304.

Preferably, as in the pixel Pix2 the grid pattern is located only on the central region 216 of the face 200, and as the notches 320 and 322 help to provide a grid-like pattern that mimics the grid pattern shown on FIG. 2, the trenches 302 and 304 are devoid of notches 320 and 322 in the first, second, third and fourth regions defined above.

As for the pixel Pix2, the pixel Pix3 preferably comprises, in each corner of the face 300, one or a plurality of V-shaped patterns each made of one trench 302 and one trench 304. In each corner, each V-shaped pattern arranged in the corner has its apex turned toward the center O of the face 300. Preferably, in each corner of the face 300, each V-shaped pattern arranged in this corner is symmetrical with respect to a diagonal of the face 300 which extends from this corner.

In the example of FIG. 3, the pixel Pix3 comprises only one V-shaped pattern in each corner.

Preferably, as in the pixel Pix2 the grid pattern is located only on the central region 216 of the face 200, and as the notches 320 and 322 help to mimic the grid pattern shown on FIG. 2, the trenches 302 and 304 of the V-shaped pattern disposed in the corners of the face 300 which are outside of the central region, and are devoid of notches 322 and 324.

Preferably, the trenches 302 comprise notches 320 only in the central region 316 and the trenches 304 comprise notches 322 only in the central region 316.

Preferably, as it is the case in the embodiment of FIG. 3, for each corner of the face 300: the pixel Pix3 comprises a plurality of V-shaped patterns each made of one trench 302 and one trench 304; the V-shaped patterns are successively and regularly arranged from this corner toward the center O of the face 300; each of the V-shaped patterns has its apex turned toward the center O of the pixel; and each of the V-shaped patterns is symmetrical with respect to a diagonal extending from this corner.

Preferably, as it is the case in the embodiment of FIG. 3, independently from the fact that the trenches 302 and 304 are arranged in V-shaped patterns, in the central region 316, for each trench 302, the notches 320 are arranged along the trench 302 with the pitch P2 of the trenches 304, and, for each trench 304, the notches 322 are arranged along the trench 304 with the pitch P1 of the trenches 302.

Preferably, as it is the case in the embodiment of FIG. 3, independently from the fact that the notches 320 are arranged with the pitch P2 and the notches 322 are arranged with the pitch P1, and independently from the fact that the trenches 302 and 304 are arranged in V-shaped patterns, for each trench 302, the notches 320 of this trench 302 are all disposed on a same side of the trench 302, and, for each trench 304, the notches 322 of this trench 304 are all disposed on the same side of the trench 304.

In the embodiment of FIG. 3, preferably, each trench 302 and each trench 322 belong to one corresponding V-shaped pattern. Said in other words, there is no trench 302 or 304 which does not belong to a V-shaped pattern. In particular, there is no pair of a trench 302 and a trench 304 in which the trenches 302 and 304 cross each other and form a X-shaped pattern.

Preferably, as it is the case in the embodiment of FIG. 3, independently from the fact that the trenches 302 and 304 are arranged in V-shaped patterns and of the pitches of the notches 320 and 322, the pattern made by the trenches 302 and 304 has a rotational symmetry by a rotation of 90° with respect to the center O of the face 300. Thanks to this rotational symmetry, the pixel Pix3 is insensitive to the polarization of this incident light.

According to an embodiment, the process of fabricating the pixel Pix3 comprises the following successive steps: forming a hard mask on the face 300; forming a photoresist mask on the hard mask; patterning the photoresist mask in order to form therein a first openings exposing the hard mask at each location of a trench 302, each location of a trench 304, each location of a notch 320 and each location of a notch 322; etching the hard mask through the first openings to form therein second openings; and etching the silicon of the photodetector of the pixel Pix3 through the second openings, to form therein the trenches 302 and 304 and the notches 320 and 322.

With the above process, it may be impossible to fabricate the pixel Pix2 of FIG. 2 as most of the portion of the photoresist mask left in place between the first openings between etching the hard mask have small dimensions in the directions X and Y and each form a small square. On the contrary, the above process may be used for fabricating the pixel Pix3 because, the portion of the photoresist mask left in place before the etching of the hard mask have bigger dimensions in the directions X and Y, and, for example, each forms a strip. Thus, this portion of the photoresist mask adhere better to the hard mask.

FIG. 4 is a schematic top view of another embodiment of the face 300 of the silicon photodetector of the pixel Pix3.

Pixels Pix3 of FIGS. 3 and 4 have a lot of elements in common, and only the differences between these two pixels will be detailed. In particular, unless indicated otherwise, all that have been indicated for the pixel Pix3 of FIG. 3 applies to the pixel Pix3 of FIG. 4.

In particular, compared to the pixel Pix3 of FIG. 3, in the pixel Pix3 of FIG. 4, the trenches 302 and 304 are not only arranged in V-shaped patterns, but also in at least one square-shaped pattern, the at least one square-shaped pattern being preferably arranged in the central region 316.

For example, as shown in the example of FIG. 4, a first trench 302 and a second trench 302 spaced from each other by a distance D taken in the X direction each crosses a first trench 304 and a second trench 304 spaced from each other by the same distance D. Preferably, the distance D is at least twice the pitches P1 and P2.

Preferably, the square-shaped pattern formed by the crossing of these four trenches 302 and 304 is centered on the center O of the face 300.

Although, in the example of FIG. 4, there is only one square-shaped pattern formed by two trenches 302 and two trenches 304, in other examples where the pixel Pix3 comprises more than one squared pattern, preferably the side of each square-shaped pattern is longer than the pitches P1 and P2 and/or each of the square-shaped pattern is centered on the center O of the face 300.

Compared with the pixel Pix3 of FIG. 3, the pixel Pix3 does not have any rotational symmetry with respect to the center O of the pixel Pix3.

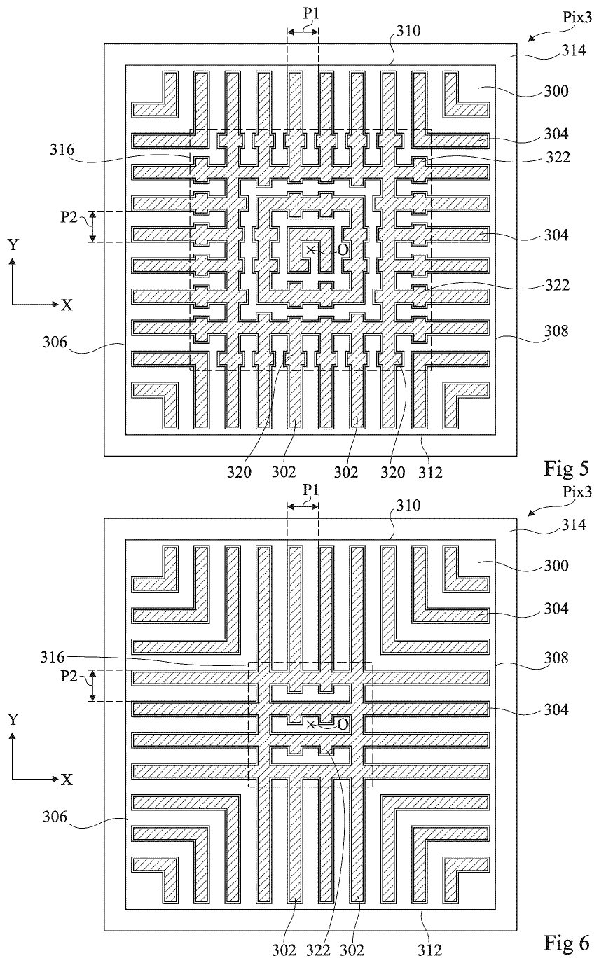

FIG. 5 is a schematic top view of another embodiment of the face 300 of the silicon photodetector of the pixel Pix3.

Pixels Pix3 of FIGS. 5 and 4 have a lot of elements in common, and only the differences between these two pixels will be detailed. In particular, unless indicated otherwise, all that have been indicated for the pixel Pix3 of FIG. 4 applies to the pixel Pix3 of FIG. 5.

In particular, compared to the pixel Pix3 of FIG. 4, in the pixel Pix3 of FIG. 5, there is more than one square-shaped pattern formed by two trenches 302 and two trenches 304. For example, in the FIG. 5, there are two square-shaped patterns, each of which being formed by two trenches 302 and two trenches 304.

For example, as it is the case in the example of FIG. 5, the pixel Pix3 does not comprise, in the central region 316, any V-shaped pattern made of one trench 302 and one trench 304. Said in other words, the pixel Pix3 does not comprise, in the example of FIG. 5, any V-shaped pattern formed by one trench 302 and on trench 304 in which the trench 302 comprises notches 320 and the trench 304 comprises notches 322.

For example, as it is the case in the example of FIG. 5, the Pix3 comprises, in each corner, outside of the central region 316, more than one V-shaped pattern formed by one trench 302 and one trench 304, these patterns being devoid of notches 320 and 322 as there are arranged outside of the central region. Further, each of these V-shaped patterns has its apex turned toward the center O of the face 300. Further, in each corner of the face 300, the V-shaped patterns arranged in the corner are successively and regularly arranged from this corner toward the center O of the face 300. Further, in each corner of the face 300, each of the V-shaped patterns arranged in the corner is symmetrical with respect to the diagonal of the face 300 which extends from this corner.

In the example of the FIG. 5, in each corner of the face 300, the pixel Pix3 comprises two successive V-shaped patterns devoid of notches 320 and 322.

Further, as it is the case in the example of FIG. 5, in the central region 316, at least some of trenches 302, preferably all the trenches 302, each comprise notches 320 on both sides (taken along the length of the trench 302) of the trench 302, and, similarly, at least some of trenches 304, preferably all the trenches 304, each comprise notches 322 on both sides (taken along the length of the trench 304) of the trench 304. Although not illustrated, in other example, each trench 302 comprises, in the central region 316, notches 320 on only one side of the trench 302, and/or each trench 304 comprises, in the central region 316, notches 322 on only one side of the trench 304.

FIG. 6 is a schematic top view of another embodiment of the face 300 of the silicon photodetector of the pixel Pix3.

Pixels Pix3 of FIGS. 4 and 6 have a lot of elements in common, and only the differences between these two pixels will be detailed. In particular, unless indicated otherwise, all that have been indicated for the pixel Pix3 of FIG. 4 applies to the pixel Pix3 of FIG. 6.

In particular, compared to the pixel Pix3 of FIG. 4, in the pixel Pix3 of FIG. 5, the central region 316 of the pixel Pix3 is smaller.

Further, and independently from the fact the region 316 is smaller, there is no V-shaped pattern whose trenches 302 and 304 comprise notches 320 and 322 respectively.

Further, and independently from the fact the region 316 is smaller and from the fact that there is no V-shaped pattern whose trenches 302 and 304 comprise notches 320 and 322 respectively, in the pixel Pix3 of FIG. 6, in the central region 316, the trenches 304 comprise notches 322 but the trenches 302 are devoid of notch 320 in the central region. Although not illustrated, the contrary is also possible, meaning that in other examples, in the central region 316, the trenches 302 comprise notches 320 but the trenches 304 are devoid of notch 322.

Simulations have shown that, for a received light in the infra-red and for a photodetector having a portion of epitaxial silicon with a thickness of 10 μm, the pixel Pix3 of FIG. 3 exhibits an improvement of 3.4% of the absorption with respect to a similar pixel Pix1, the pixel Pix3 of FIG. 4 exhibits an improvement of 3.8% of the absorption with respect to a similar pixel Pix1, the pixel Pix3 of FIG. 5 exhibits an improvement of 3.0% of the absorption with respect to a similar pixel Pix1, and the pixel Pix3 of FIG. 6 exhibits an improvement of 3.4% of the absorption with respect to a similar pixel Pix1.

Preferably, in the pixel Pix3, as illustrated in all the embodiments previously described in relation with FIGS. 3, 4, 5 and 6, there is no square-shaped pattern formed by the intersection of two tranches 302 with two corresponding trenches 304 whose sides length is equal to the pitches P1 and P2. Said in other words, there is no square-shaped pattern formed by the intersection of two successive (or neighboring) trenches 302 with two successive (or neighboring) trenches 304.

Preferably, in the pixel Pix3, as illustrated in all the embodiments previously described in relation with FIGS. 3, 4, 5 and 6, outside of the central region 316, the trenches 302 and 304 do not comprise any notch respectively 320 and 322.

Although it has not been explicitly indicated previously, in the pixel Pix3 each trench 302 which comprises a portion outside the region 316 and a portion inside the region 316 is devoid of notch 320 on its portion outside the region 316 and may comprises notches 322 on its portion inside the region 316. Similarly, in the pixel Pix3 each trench 304 which comprises a portion outside the region 316 and a portion inside the region 316 is devoid of notch 322 on its portion outside the region 316 and may comprises notches 322 on its portion inside the region 316.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A pixel, comprising:
a silicon portion having a first face configured to received light;
first trenches penetrating into the silicon portion from the first face, wherein said first trenches extend parallel to a first direction and are regularly spaced in a second direction perpendicular to the first direction; and
second trenches penetrating into the silicon portion from the first face, wherein the second trenches extend parallel to the second direction and are regularly spaced in the first direction; and
in a central region of the first face:
the first trenches include first notches penetrating into the silicon from the first face, wherein each first notch extends from a first trench toward a neighboring first trench without reaching said neighboring first trench, and wherein each first notch is aligned with a corresponding second trench.

2. The pixel according to claim 1, wherein in said central region of the first face;
the second trenches include second notches penetrating into the silicon from the first face, wherein each second notch extends from a second trench toward a neighboring second trench without reaching said neighboring second trench, and wherein each second notch is aligned with a corresponding first trench.

3. The pixel according to claim 2, wherein the first face has two first sides parallel to the first direction and two second sides parallel to the second direction.

4. The pixel according to claim 3, wherein the first face comprises:
a first region extending from a first one of the first sides toward the central region, the first region comprising only second trenches;
a second region extending from a second one of the first sides toward the central region, the second region comprising only second trenches;
a third region extending from a first one of the second sides toward the central region, the third region comprising only first trenches;
a fourth region extending from a second one of the second sides toward the central region, the fourth region comprising only first trenches.

5. The pixel according to claim 4, wherein there are no notches on the first trenches in the first and third regions.

6. The pixel according to claim 4, wherein there are no notches on the second trenches in the second and fourth regions.

7. The pixel according to claim 3, further comprising at least one V-shaped pattern made of one first trench connected to one second trench, wherein the at least one V-shaped pattern is arranged in a corner of the first face, outside the central region.

8. The pixel according to claim 7, wherein, in the corner of the first face, said at least one V-shaped pattern arranged symmetrical with respect to a diagonal of the first face extending from said corner, and wherein the at least one V-shaped pattern has an apex turned toward the center of the first face.

9. The pixel according to claim 3, further comprising a plurality of V-shaped patterns, each V-shaped pattern made of one first trench, wherein the plurality of V-shaped patterns are arranged in a corner of the first face, outside the central region.

10. The pixel according to claim 9, wherein the plurality of V-shaped patterns are successively and regularly arranged from said corner toward the center of the first face, each of said V-shaped patterns having an apex turned toward the center of the first face, each of said V-shaped patterns being symmetrical with respect to a diagonal extending from said corner.

11. The pixel according to claim 10, wherein the first trenches of the plurality of V-shaped patterns comprise first notches in the central region and/or wherein the second trenches of the plurality of V-shaped patterns comprise second notches in the central region.

12. The pixel according to claim 3, wherein, in the first direction, the central region has a length comprised between 50 and 70% of the length of each first side, and, in the second direction, the central region has a length comprised between 50 and 70% of the length of each first side.

13. The pixel according to claim 2, wherein, in the central region, the first trenches are aligned on first lines of a grid pattern and the second trenches are aligned on second lines of a grid pattern, the first notches being aligned on the second lines of the grid pattern and the second notches being aligned with the first lines.

14. The pixel according to claim 2, wherein, in the central region, the first and second trenches together with the first and second notches form a grid-like pattern.

15. The pixel according to claim 2, wherein the first and second trenches together with the first and second notches form a pattern having a 900 rotational symmetry with respect to the center of the first face.

16. The pixel according to claim 2, wherein the first trenches are disposed with a first pitch in the second direction and the second trenches are disposed with a second pitch in the first direction, the first and second pitches being equal to each other and comprised between 300 and 600 nm.

17. The pixel according to claim 15, wherein the length of the first notches in the second direction and the length of the second notches in the first direction are comprised between 40 and 60% of the first and second pitches.

18. The pixel according to claim 1, wherein a width of the first trenches is equal to a width of the second trenches, the width of the first and second trenches being comprised between 150 and 250 nm.

19. The pixel according to claim 1, wherein the light is infra-red light.

20. A method of fabricating the pixel according to claim 2, comprising:
forming a hard mask on the first face of the pixel;
forming a photoresist mask on the hard mask;
patterning the photoresist mask in order to form therein a first opening exposing the hard mask at each location of a first trench, each location of a second trench, each location of a first notch and each location of a second notch;
etching, through said first openings, second openings in the hard mask; and
etching, through said second openings, the first and second trenches and the first and second notches in the silicon portion.
